(19) United States
(12) Patent Application Publication
(10) Pub. No.: US 2007/0121369 A1
(43) Pub. Date: May 31, 2007

(54) Resistive memory cell arrangement and a semiconductor memory including the same

(76) Inventor: Thomas Happ, Tarrytown, NY (US)

Correspondence Address: EDELL, SHAPIRO & FINNAN, LLC, 1901 RESEARCH BLVD., SUITE 400, ROCKVILLE, MD, 20850, US

(21) Appl. No.: 11/604,397

(22) Filed: Nov. 27, 2006

Related U.S. Application Data
(63) Continuation of application No. PCT/DE05/00928, filed on May 20, 2005.

(30) Foreign Application Priority Data
May 27, 2004 (DE) 102004026003.6

(51) Int. Cl. G11C 11/00

(52) U.S. Cl. 365/148

(57) ABSTRACT

A memory cell arrangement includes a set of word lines and bit lines and at least one chain of series-connected memory elements which is electrically connected to one of the bit lines. The memory elements each include a resistive memory cell, which can be switched between a low-resistance ON state and a high-resistance OFF state, and a transistor which is electrically connected to the resistive memory cell in a parallel circuit. The ON resistance of the transistor, which has been turned on, of a memory element is smaller than the ON resistance of the memory cell which has been switched to its low-resistance ON state. Each transistor in a respective chain is electrically connected to one of the word lines.

### CROSS REFERENCE TO RELATED APPLICATIONS

This application is a continuation of International Application No. PCT/DE2005/000928, filed on May 20, 2005, entitled “Resistive Memory Cell Arrangement,” which claims priority under 35 U.S.C. §119 to Application No. DE 102004026003.6 filed on May 27, 2004, entitled “Resistive Memory Cell Arrangement,” the entire contents of which are hereby incorporated by reference.

### BACKGROUND

Flash memories are frequently used nowadays in modem electronic systems as nonvolatile memories. Although flash memory technology, in particular, has been scaled to the range below 100 nm in recent years, the disadvantages of long write/erase times, which are typically in the milliseconds range, a high write voltage, which is typically in the range of 10 to 13 V, and a consequently high programming energy have not been able to be solved to date, which is an obstacle to the desire for further miniaturization, however. Furthermore, the method for fabricating the flash memory cells is costly and comparatively complex.

In contrast to this, memory modules based on resistive memory cells, in particular so-called CBRAM (Conductive Bridging RAM) memory cells, represent a new and promising technology for semiconductor-based memory modules. With this type of memory module, a resistive memory cell can be switched between a high-resistance state (“OFF” state) and a low-resistance state (“ON” state) via electrical pulses, thus making it possible to store a quantity of information (1 bit).

Specifically, a resistive CBRAM memory cell is constructed from an inert electrode, a reactive electrode and a highly resistive—but conductive for ions—carrier material (solid electrolyte) which is arranged between these two electrodes. The two electrodes form, together with the solid electrolyte, a redox system in which a redox reaction takes place above a defined threshold voltage. Depending on the polarity of a voltage which is applied to the two electrodes but must be greater than the threshold voltage, the redox reaction can take place in one reaction direction or the other, metal ions being produced or discharged. Metal ions produced at the reactive electrode are reduced in the solid electrolyte and form metallic precipitates which increase in their number and size until finally a low-resistance current path which bridges the two electrodes forms. In this state, the electrical resistance of the solid electrolyte is significantly reduced, for instance by several orders of magnitude, in comparison with the state without a low-resistance current path, as a result of which the ON state of the CBRAM memory cell is defined with respect to the OFF state without a low-resistance current path. CBRAM memory cells are thus based on a percolative switching effect.

In this case, chalcogenides, in particular, have been investigated regarding their suitability as a carrier material. However, a commercially available product based on CBRAM memory cells currently still does not exist.

Two different circuit variants for the construction of large-scale integrated memories from resistive memory cells are have been proposed by ones skilled in the art, e.g., a so-called “cross-point” circuit construction with diode isolation. The typical cross-point memory cell architecture with diode isolation is shown in FIG. 1. A resistive memory cell 1 with a series-connected diode 2 is respectively connected, at the crossover points between a bit line BL and a word line WL, to the bit line associated with the crossover point and to a word line. If, for example, a voltage of +½ V is applied to the bit line BLₙ, while a voltage of −½ V is applied to the word line WLₙ, the resistive memory cell 1 arranged at the crossover point between the bit line BLₙ and the word line WLₙ can be switched, for example, from its OFF state to its ON state if the threshold voltage needed to switch the resistive memory cell is less than 1 V.

Such a construction which is shown in FIG. 1 advantageously allows a very compact memory cell array architecture with a minimum area requirement of 4 F² for each memory cell, F denoting the minimum structure spacing (currently approximately 100 nm) which can be achieved using lithography. However, this construction has the considerable disadvantage that, when writing to/erasing individual memory cells, interference voltages occur in the adjacent cells on the same bit line or word line. If the word lines adjoining the word line WLₙ are kept, for example, at a potential of 0 V, the interference voltages result in a voltage of +½ V, for example, being dropped across the memory cells which are connected to the bit line BLₙ. However, this may even result in undesirable switching of memory cells on account of the generally random distribution of the threshold voltage of resistive memory cells. The diodes which are connected in series with the resistive memory cells may prevent such undesirable switching effects in their reverse direction but not in their forward direction.

As an alternative to the cross-point cell architecture with diode isolation shown in FIG. 1, a 1-transistor/1-resistor (1T1R) arrangement at the crossover points between bit lines and word lines has also been proposed. FIG. 2 shows a typical construction of such a 1T1R memory cell arrangement. In this case, each resistive memory cell 1 is connected, on the one hand, to a bit line (BL) while it is connected to ground via a bipolar transistor 3. The control connection of the bipolar transistor 3 is additionally connected to a word line WL. As can be seen, the resistive memory cell can be switched only if the bipolar transistor 3 is turned on by the word line.

Although such a construction which is shown in FIG. 2 affords improved isolation of the individual memory cells, it cannot prevent interference voltages, which are caused by capacitive coupling, in particular, being applied at least to that end of a memory cell which is connected to the bit line. This has a very unfavorable effect, particularly in the case of memory concepts having a comparatively low operating voltage, for example in the case of CBRAM memory cells having an operating voltage of approximately 0.3 V, for example, since it is probable in this case that memory cells will be inadvertently switched. In addition, this circuit construction can be realized only with an area requirement of at least 6 F² for each memory cell, which is an obstacle to further miniaturization of the circuit construction.

### SUMMARY

A memory cell arrangement includes a plurality of word lines and bit lines and at least one chain of series-connected memory elements which is electrically connected to one of the bit lines. The memory elements each include a resistive memory cell, which can be switched between a low-resistance ON state and a high-resistance OFF state, and a transistor which is electrically connected to the resistive memory cell in a parallel circuit. The ON resistance of the transistor, which has been turned on, of a memory element is smaller than the ON resistance of the memory cell which has been switched to its low-resistance ON state. Each transistor in a respective chain is electrically connected to one of the word lines.

The above and still further features and advantages of the device will become apparent upon consideration of the following definitions, descriptions and descriptive figures of specific embodiments thereof, wherein like reference numerals in the various figures are utilized to designate like components. While these descriptions go into specific details, it should be understood that variations may and do exist and would be apparent to those skilled in the art based on the descriptions herein.

### BRIEF DESCRIPTION OF THE DRAWINGS

The device is explained in more detail below with reference to exemplary embodiments, where:

FIG. 1 shows a conventional so-called cross-point cell architecture of resistive memory cells with diode isolation;

FIG. 2 shows a conventional so-called 1-transistor/1-resistor arrangement of memory cells;

FIG. 3 shows one embodiment of the memory cell arrangement according to the described device;

FIG. 4A shows the chain of memory elements of FIG. 3 of the memory cell arrangement according to the described device, in which no memory cell has been selected;

FIG. 4B shows the chain of memory elements of FIG. 3 of the memory cell arrangement according to the described device, in which a memory cell has been selected; and

FIG. 5 shows, for example, a layout for the memory cell arrangement according to the described device.

### DETAILED DESCRIPTION

The described device relates to an arrangement of resistive memory cells which can be used to avoid the disadvantages of the memory cell arrangements which were previously described and are known in the prior art. In particular, such an arrangement makes it possible to write to/erase individual memory cells in an isolated manner and to simultaneously avoid unintentional write/erase operations on memory cells as a result of parasitic interference voltages. In addition, such a circuit construction allows for further miniaturization of memory modules.

A memory cell arrangement, including a plurality of word and bit lines, comprises at least one chain of series-connected memory elements electrically connected to one of the bit lines. Each memory element in a chain is respectively constructed from a resistive memory cell and a transistor which is electrically connected to the latter in a parallel circuit. The resistive memory cell can be switched between a low-resistance ON state and a high-resistance OFF state. The electrical resistance of the resistive memory cell in its high-resistance OFF state is generally several orders of magnitude greater than the electrical resistance in its low-resistance ON state. However, the ON resistance of a transistor, i.e., the resistance of the transistor which has been turned on, of a memory element is smaller than the ON resistance, i.e., the resistance of the low-resistance state, of the resistive memory cell of the memory element, such that the resistive memory cell is essentially short-circuited by the transistor when the latter is turned on.

Furthermore, each transistor of a memory element in a chain of series-connected memory elements is electrically connected to one of the word lines. In this case, each transistor in a chain is generally electrically connected to a word line other than the word lines of the other transistors in the chain, an individual word line respectively generally connecting an individual transistor in different chains of series-connected memory elements in an electrically conductive manner.

The transistor of a memory element may be a field effect transistor or a bipolar transistor. If the transistor is a field effect transistor, the resistive memory cell which is connected in parallel with the field effect transistor is electrically connected to the source and drain of the field effect transistor. The word line which is then connected to the field effect transistor is electrically connected to the gate of the field effect transistor. If the transistor is a bipolar transistor, the memory cell which is connected in parallel with the bipolar transistor is electrically connected to the emitter and collector of the bipolar transistor. The word line which is then connected to the bipolar transistor is electrically connected to the base of the bipolar transistor.

In general, a plurality of chains of series-connected memory elements are electrically connected to an individual bit line in the resistive memory cell arrangement according to the described device, each chain of series-connected memory elements being electrically connected to the bit line via a selection component. Such a selection component (e.g., a selection transistor) in particular, is used to select a chain of memory elements, which is connected to a bit line, from the plurality of chains of memory elements which are connected to the bit line. The selection transistor may be a field effect transistor or a bipolar transistor. If the selection transistor is a field effect transistor, a word line is advantageously connected to the gate of the field effect transistor in order to switch the field effect transistor. If the selection transistor is a bipolar transistor, the base of the bipolar transistor is advantageously connected to a word line in order to turn on the bipolar transistor.

As previously explained above, the transistor which has been turned on is intended to essentially short-circuit the resistive memory cell, for which purpose the ON resistance of the transistor must be smaller than the ON resistance of the resistive memory cell. The expression “essentially short-circuit” is used to mean that, when the transistor is in the ON state and the resistive memory cell is in the ON state (or OFF state), the electrical current essentially flows through the transistor when a voltage is applied to the memory element. In one particularly advantageous refinement of the resistive memory cell and the transistor, the ON resistance of the resistive memory cell may be approximately 10 times to approximately 1000 times the ON resistance of the transistor. This makes it possible for the parasitic current through the short-circuited resistive memory cell to be limited to at most approximately 10% to at most approximately 1% of the current through the transistor which has been turned on.

Since the transistor resistances of the series-connected transistors in a chain of memory elements are added together, they represent a parasitic additional resistance with respect to a selected memory resistance of a resistive memory cell. In order to be able to write a sufficiently noise-free electrical signal to the memory cell, and read the signal from the latter, in a simple manner, the parasitic additional resistance of the transistors in a chain of memory elements must not become too large. More precisely, the number of transistors which can be connected in series in an individual chain depends on the relative size of this parasitic additional resistance with respect to the memory cell resistance of an individual resistive memory cell. For example, if a transistor resistance of approximately 1 kohm is used as a basis, the parasitic additional resistance of the transistors is negligibly low in comparison with the ON resistance (e.g., 10⁴-10⁵ ohms) of, for example, a CBRAM memory cell with 8 memory elements in each chain. In the resistive memory cell arrangement according to the described device, at most 10⁴ transistors, but preferably only between 10 to 100 transistors, are respectively connected in series in a chain of memory elements.

As previously explained, the chains having the series-connected memory elements are each advantageously electrically connected to a bit line via a selection component. In this case, the respective other end of the chains of series-connected memory elements is connected to a fixed potential which may be, for example, ground or the potential of a voltage source. As an alternative, the end of a chain may also be connected to the output of a current source or to the input of a sense amplifier or a similar evaluation circuit.

The memory cell arrangement according to the described device may be of very compact design. In particular, when self-aligned contacts to source/drain regions are used, a memory cell arrangement having a space requirement of (4+x)F² for each memory cell can be realized despite complete isolation of the individual memory resistances. The excess of (+x) results from the effective proportion of the selection component, in particular selection transistor, required for each chain of memory elements and, if appropriate, from additionally required alignment tolerances for patterning the gate stack, contacts or memory resistances. According to the described device, a maximum address line spacing, that is to say bit line spacing or word line spacing, of 2 F is preferred, F denoting the minimum spacing which can be achieved using lithographic methods, as previously explained.

The resistive memory cells of the memory cell arrangement according to the described device are advantageously CBRAM memory cells (solid electrolyte memory cells). A glass, in particular a semiconductive material, is advantageously selected as the solid electrolyte. The solid electrolyte particularly preferably comprises at least one alloy containing at least one chalcogen, i.e., an element from main group VI of the periodic table such as O, S, Se, Te. A vitreous chalcogenide alloy may, for example, be: Ge-S, Ge-Se, Ni-S, Cr-S or Co-S. The solid electrolyte may also be a porous metal oxide such as: WOₓ, Al₂O₃, VOₓ or TiOₓ. The material of the reactive electrode may be a metal which is selected, for example, from: Cu, Ag, Au, Ni, Cr, V, Ti or Zn. The inert electrode may comprise a material which is selected, for example, from: W, Ti, Ta, TiN, doped Si and Pt. It is also preferred for the threshold voltage for activating the redox system, i.e., for starting the redox reaction for producing metal ions at the anodic electrode, to be at most 5 V. It is preferable if the threshold voltage is at most 2 V and is even more preferable if the threshold voltage is below 1 V, the threshold voltage typically being in the range from 200 to 500 mV. The two electrodes may be at a distance from one another which is in the range from 10 nm to 250 nm and is, for example, 50 nm.

The resistive memory cells of the memory cell arrangement according to the described device may also be a phase change memory cell. In the case of a phase change memory cell, the phase change material can be switched between two states with a different electrical resistance. In this case, these two states with a different electrical resistance can generally be assigned to different structural phase states such as a generally amorphous phase state or a generally crystalline phase state, so that switching between the states with a different electrical resistance is associated with a change in the phase state. In this case, the amorphous or crystalline phase states generally correspond to states with a different long-range order. However, it is equally also possible for the at least two states with a different electrical resistance to be distinguished within a single, for example completely amorphous or completely crystalline, phase state. Typical materials which are suitable as the phase change material, in known phase change memories, are alloys containing at least one chalcogen.

Perovskite memory cells are also known in the art and are suitable as resistive memory cells. In the case of such perovskite memory cells, a structure transition between a high-resistance state and a low-resistance state is caused by the injection of charge carriers.

Amorphous hydrogenated silicon (Si:H) memory cells can also be used as resistive memory cells. In the case of such known memory cells, amorphous Si between two metal electrodes can be switched between a high-resistance state and a low-resistance state via electrical pulses subsequent to a forming step.

Known polymer/organic memories based, for example, on charge transfer complexes are also suitable for the resistive memory cells, the polymer/organic memories likewise being able to be switched between a high-resistance state and a low-resistance state.

Depending on their specific design, the resistive memory cells have different ON resistances. However, according to the described device, it is preferred if the resistive switching element has an ON resistance in the range of approximately 10 kohm to approximately 100 kohm. Such an ON resistance is realized, for example, in phase change memory cells and CBRAM memory cells.

The memory cell arrangement according to the described device makes it possible, in an extremely advantageous manner, to realize a very compact memory cell array architecture having a minimum address line spacing of 2 F. In contrast to the memory cell arrangements which were described at the outset and are known in the prior art, interference voltages when writing to and erasing individual memory cells, which have an effect on other adjacent memory cells, can be avoided via the memory cells which have been short-circuited using the respective transistors of a memory element. The individual memory cells are driven using bit lines and the word lines which use the transistor gates or transistor bases to turn on the individual transistors and thus short-circuit the associated memory resistance. The resistive memory cells which have been bridged in this manner are transparent to read or erase operations, since the current respectively flows only via the bypass transistor, and thus do not contribute to the read signal during read operations. Only when the transistor of a memory element associated with the memory cell is switched off is it possible to read from or write to or erase this memory cell. When a resistive memory cell within a chain is activated, the associated transistor is thus switched off, with the result that a voltage signal that is applied to the chain is completely dropped across the memory cell selected in this manner or a current signal follows the path via the bypass transistors which have not been selected and the one memory resistance which has been selected. The selection component, in particular the selection transistor, is used in this case to select the desired bit line from among the many individual chains on a bit line.

In the following paragraphs, exemplary embodiments of the device are described in connection with the figures.

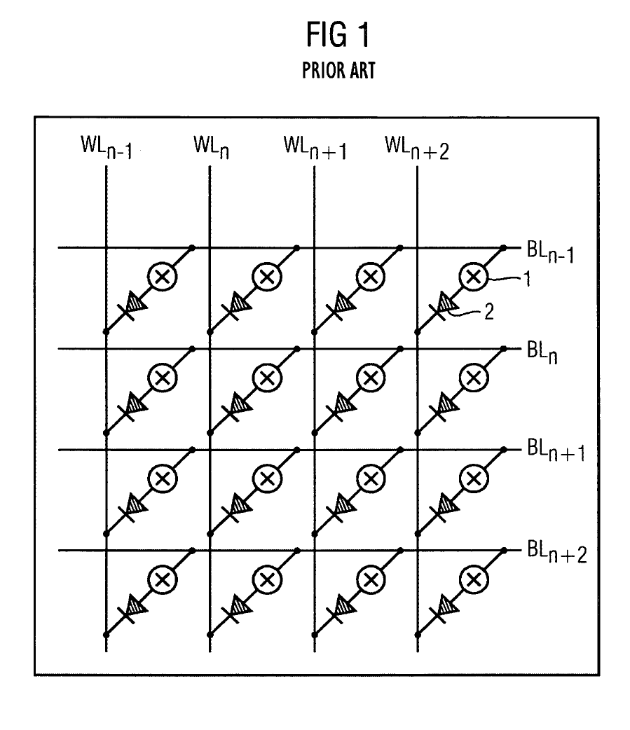

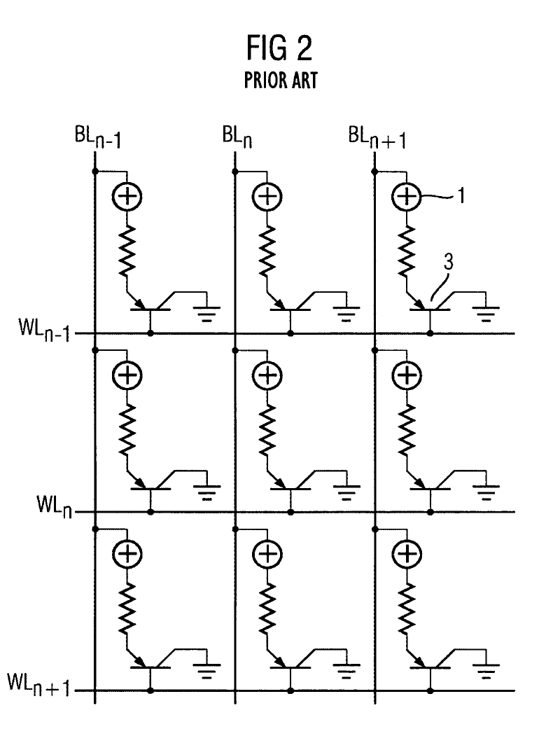

FIGS. 1 and 2 each show a resistive memory cell arrangement which is known in the prior art, has already been described at the outset and therefore no longer needs to be explained in any more detail here.

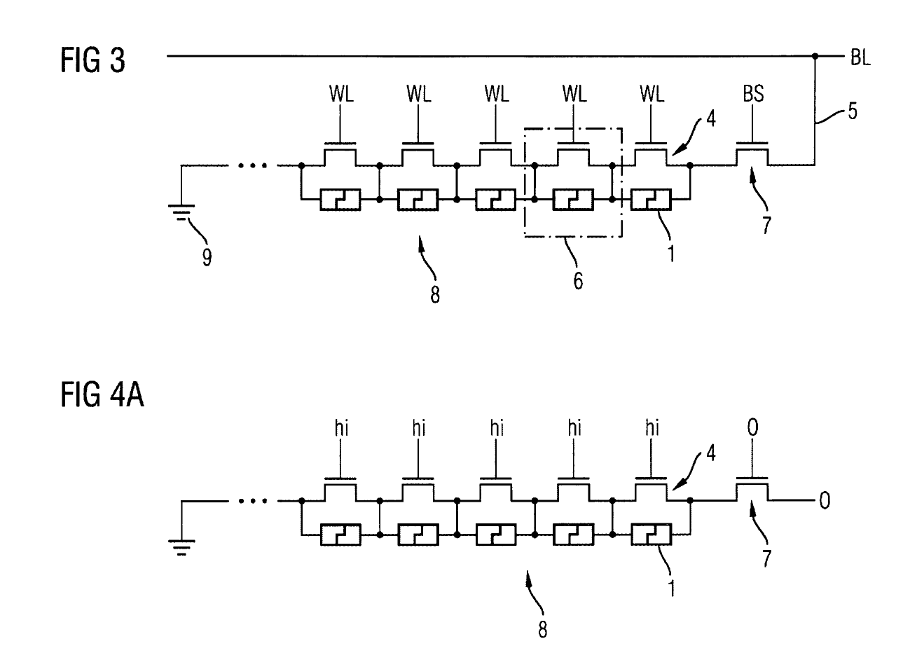

FIG. 3 shows, for example, a chain architecture for a resistive memory cell arrangement according to the described device. According to FIG. 3, a chain of series-connected memory elements 6 (five illustrated in this case) is electrically connected, via a selection transistor 7, to an electrical connecting line 5 which is electrically connected to a bit line BL. Each memory element 6 is composed of a transistor 4 in the form of a field effect transistor with a resistive memory cell 1 connected in parallel with the latter. The gates of the field effect transistors 4 are each electrically connected to a separate word line WL. A ground end of each chain 8 is connected to ground 9, the ground end being opposite the end of the chain 8 that is electrically connected to a bit line BL. In addition, all of the resistive memory cells 1 are electrically connected to one another. Although only six memory elements 6 are illustrated in the drawing of FIG. 3, the repetition points are used to indicate that further memory elements can be attached to the chain 8. The number of memory elements 6, which are connected in series within the chain 8, results in this case from the ratio between the ON resistance of a field effect transistor 4 and the ON resistance of a resistive memory cell 1, in other words, from a ratio between the parasitic transistor resistances and the ON resistance of a resistive memory cell 1 that is suitable for practical measurement.

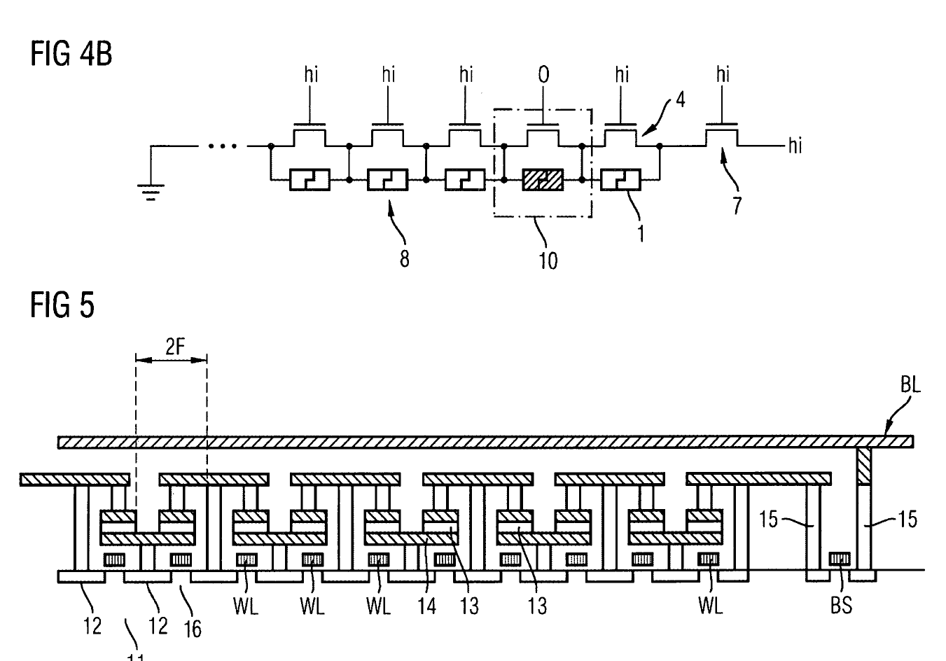

FIGS. 4A and 4B illustrate the process of selecting a resistive memory cell 1 within the chain of memory elements shown in FIG. 3. In this case, FIG. 4A shows a state in which no resistive memory cell 1 in the chain 8 has been activated. In this state, all of the field effect transistors 4, except for the selection transistor 7, are switched on (i.e., are at a high potential hi). In other words, the field effect transistors 4 are turned on. In this manner, all of the resistive memory cells 1 are short-circuited by the field effect transistors 4, with the result that a current signal follows the path via the field effect transistors 4.

In FIGS. 4A and 4B, all of the field effect transistors are, for example, of the enhancement mode type, so that a high potential hi must be applied to the gate of a field effect transistor in order to turn it on. However, it is equally possible for the field effect transistors to be of the depletion mode type (normally on), only the word line drive levels being inverted in this case.

Since the chain 8 has not been selected in FIG. 4A, a potential 0 is applied to the gate of the selection transistor 7. The potential 0 is likewise applied to the bit line BL in this state since no memory cell has been activated.

FIG. 4B shows a state in which a potential 0 is applied to a word line, with the result that the associated field effect transistor 4 is off. In addition, a high potential (hi) is applied to the gate of the selection transistor 7, with the result that the selection transistor 7 is turned on and the chain 8 is selected. A high potential (hi) is likewise applied to the bit line BL.

Turning off the field effect transistor 4 in the memory element 10 causes the high potential hi which is applied to the chain 8 via the bit line BL to be completely dropped across the memory cell 1 that has been selected in this manner or a current signal to follow the path via the bypass transistors which have not been selected and the one resistive memory cell 1 which has been selected. The resistive memory cell 1 selected in this manner can now be written to or erased and read from, all of the other resistive memory cells 1 in the chain 8 being short-circuited via their respective drive transistors 4, which reliably prevents fluctuations in potential and similar signals.

FIG. 5 shows, for example, one possible layout with a cell size of (4+x)F². FIG. 5 shows the section through a semiconductor substrate 11 along a bit line BL. The connection zones 12 (i.e., the source or drain) of the field effect transistors are formed in the semiconductor substrate 11. The gates of the field effect transistors, which correspond to the word lines WL, are situated in the vicinity of the connection zones 12 above a channel zone 16 that is arranged between the connection zones 12. Resistive memory cells 13 are situated above the word lines WL, two memory cells respectively being connected to one another via an electrical contact 14. The resistive memory cells 13 are in the form of CBRAM memory cells having two electrodes and a solid electrolyte which is arranged between the two electrodes. The electrodes of the resistive memory cells 13 are connected to one another via electrical contacts 15, with the result that the memory elements, which are each constructed from a resistive memory cell and a field effect transistor, are connected in series. As shown in FIG. 5, the minimum spacing between adjoining electrical contacts 15 is 2 F. The spacing between adjoining word lines WL and adjoining bit lines BL is likewise 2 F.

While the device has been described in detail with reference to specific embodiments thereof, it will be apparent to one of ordinary skill in the art that various changes and modifications can be made therein without departing from the spirit and scope thereof. Accordingly, it is intended that the described device covers the modifications and variations of this device provided they come within the scope of the appended claims and their equivalents.

What is claimed is:

1. A memory cell arrangement, comprising:
a plurality of word lines;
a plurality of bit lines; and
at least one chain of series-connected memory elements, the chain being electrically connected to a respective one of the bit lines;
wherein each memory element, comprises:
a resistive memory cell operable to be switched between a low-resistance ON state and a high-resistance OFF state; and
a transistor electrically connected to the resistive memory cell in parallel, the transistor being electrically connected to a respective one of the word lines, wherein an ON resistance of the transistor in an activate state is less than an ON resistance of the resistive memory cell in the low-resistance ON state.

2. The memory cell arrangement as claimed in claim 1, wherein the at least one chain is connected to a respective bit line via a selection transistor.

3. The memory cell arrangement as claimed in claim 1, wherein the ON resistance of the resistive memory cell is approximately between 10 times to 1000 times the ON resistance of the transistor.

4. The memory cell arrangement as claimed in claim 1, wherein a chain of the at least one chain is electrically connected to one of: a current source, a voltage source, an input of a sense amplifier, and ground.

5. The memory cell arrangement as claimed in claim 1, wherein the transistor is a field effect transistor.

6. The memory cell arrangement as claimed in claim 1, wherein at most 10⁴ transistors are respectively connected in series in the at least one chain.

7. The memory cell arrangement as claimed in claim 1, wherein at most between 10 to 100 transistors are respectively connected in series in the at least one chain.

8. The memory cell arrangement as claimed in claim 1, wherein the bit lines and word lines have a maximum address line spacing of approximately 2 F, where F is a minimum structure spacing.

9. The memory cell arrangement as claimed in claim 1, wherein the resistive memory cell is one selected from the group including: a solid electrolyte memory cell, a phase change memory cell, a perovskite memory cell, an amorphous hydrogenated silicon memory cell and a polymer/organic memory cell.

10. The memory cell arrangement as claimed in claim 1, wherein the ON resistance of the resistive memory cell is in the range from approximately 10 kohms to approximately 100 kohms.

11. A semiconductor memory comprising:
a memory cell arrangement, the memory cell arrangement comprising:
a plurality of word lines;
a plurality of bit lines; and
at least one chain of series-connected memory elements, the chain being electrically connected to a respective one of the bit lines;
wherein each memory element, comprises:
a resistive memory cell operable to be switched between a low-resistance ON state and a high-resistance OFF state; and
a transistor electrically connected to the resistive memory cell in parallel, the transistor being electrically connected to a respective one of the word lines, wherein an ON resistance of the transistor in an activate state is less than an ON resistance of the resistive memory cell in the low-resistance ON state.

12. The semiconductor memory as claimed in claim 11, wherein the at least one chain is connected to a respective bit line via a selection transistor.

13. The semiconductor memory as claimed in claim 11, wherein the ON resistance of the resistive memory cell is approximately between 10 times to 1000 times the ON resistance of the transistor.

14. The semiconductor memory as claimed in claim 11, wherein a chain of the at least one chain is electrically connected to at least one of: a current source, a voltage source, an input of a sense amplifier, and a ground.

15. The semiconductor memory as claimed in claim 11, wherein the transistor is a field effect transistor.

16. The semiconductor memory as claimed in claim 11, wherein at most 10⁴ transistors are respectively connected in series in the at least one chain.

17. The semiconductor memory as claimed in claim 11, wherein at most between 10 to 100 transistors are respectively connected in series in the at least one chain.

18. The semiconductor memory as claimed in claim 11, wherein the bit lines and word lines have a maximum address line spacing of approximately 2 F, where F is a minimum structure spacing.

19. The semiconductor memory as claimed in claim 11, wherein the resistive memory cell is one of: a solid electrolyte memory cell, a phase change memory cell, a perovskite memory cell, an amorphous hydrogenated silicon memory cell, and a polymer/organic memory cell.

20. The semiconductor memory as claimed in claim 11, wherein the ON resistance of the resistive memory cell is in the range from approximately 10 kohms to approximately 100 kohms.

21. An electronic device including a semiconductor memory with a memory cell arrangement, the memory cell arrangement comprising:
a plurality of word lines;
a plurality of bit lines; and
at least one chain of series-connected memory elements, the chain being electrically connected to a respective one of the bit lines;
wherein each memory element, comprises:
a resistive memory cell operable to be switched between a low-resistance ON state and a high-resistance OFF state; and
a transistor electrically connected to the resistive memory cell in parallel, the transistor being electrically connected to a respective one of the word lines, wherein an ON resistance of the transistor in an activate state is less than an ON resistance of the resistive memory cell in the low-resistance ON state.
